(19) United States
(12) Patent Application Publication
(10) Pub. No.: US 2009/0068529 A1
(43) Pub. Date: Mar. 12, 2009

(54) SILICIFIED ELECTROLYTE MATERIAL FOR FUEL CELL, METHOD FOR ITS PREPARATION AND FUEL CELL USING SAME

(75) Inventors: Steve Martin, ST SAUVEUR (FR); Marc Plissonnier, EYBENS (FR); Pascal Faucherand, SASSENAGE (FR); Lucie Jodin, NANCY (FR)

Correspondence Address: BURR & BROWN, PO BOX 7068, SYRACUSE, NY, 13261-7068, US

(73) Assignee: Commissariat A L'Energie Atomique, Paris (FR)

(21) Appl. No.: 11/871,423

(22) Filed: Oct. 12, 2007

(30) Foreign Application Priority Data
Nov. 13, 2006 (FR) 06.54858

(51) Int. Cl. H01M 8/10; C23C 16/513

(52) U.S. Cl. 429/33; 427/578

(57) ABSTRACT

This material suitable for constituting an electrolyte for a fuel cell has a hydrophobic matrix comprising carbon, fluorine, oxygen and hydrogen, and silicon.

### FIELD OF THE INVENTION

The present invention relates to a material suitable for constituting the electrolyte of a fuel cell. This material has a matrix comprising carbon (C), fluorine (F), oxygen (O) and hydrogen (H), and silicon (Si).

The material of the present invention serves to improve the performance of the electrolyte comprising same, and therefore, of the fuel cell incorporating such an electrolyte.

### PRIOR ART

One of the currently researched applications of fuel cells consists in powering a portable electronic apparatus, such as a computer or a cellular telephone. These applications are often qualified as “nomad” because the apparatus with its fuel cell must be transportable. It therefore appears important to reduce the size and weight of such a cell, while preserving or even improving its electrical performance. To reconcile size reduction with superior electrical performance, attempts are under way to substantially increase the “active” or real surface area of the active compounds of this fuel cell, including that of the electrolytic membranes.

FIG. 1 shows a fuel cell of the prior art in a cross section. In a manner known per se, such a fuel cell comprises a ceramic substrate 101, several hundred microns thick, whereon a layer of porous ceramic 102 is deposited. The ceramic layer 102 is porous to the hydrogen (H₂) gas conveyed by the feed channels 105 to the interface between the planar cathode 103 and the matching planar anode 104.

This type of fuel cell is qualified as a Proton Exchange Membrane Fuel Cell, because it comprises a membrane forming the electrolyte 106 made from a good proton conducting material.

To favor the oxidation and reduction half-reactions occurring in the cell, it is in fact necessary for this electrolyte to have high proton (H⁺) conduction.

As shown in FIG. 1, the electrodes 103 and 104 and the electrolyte 106 have a substantially planar shape. In fact, the area of the interface between the electrodes and the electrolyte directly determines the quantities of reagents used, and hence the electric power supplied by the cell. This is why it is desirable to increase the area of this interface between the electrodes and the proton conducting electrolyte.

However, due to the necessary limitation of the cell dimensions, the reliefs or roughnesses whereof the formation is desired at the interface between the electrodes demand high accuracy in the deposition of the electrolyte, in order to form matching deposits, that is, matching the topography of the porous ceramic substrate. Such matching deposits in fact serve to preserve the geometry of the reliefs developed on the substrate, thereby also ensuring the electrical continuity of the electrodes and of the membrane electrolyte.

Furthermore, the electrolytic membrane must have a high proton conduction, while chemically and mechanically resisting the water and solvents employed during the fabrication of the fuel cell.

Among the materials of the prior art suitable for constituting an electrolyte, mention can be made of Nafion® (for example, described in patent U.S. Pat. No. 3,692,569), a trade name denoting a fluorocarbon polymer, that is, an organic structure in which the hydrogen atoms combined with the carbon atoms have been replaced by fluorine atoms. More precisely, Nafion® comprises a polymer formed by flexible fluorine chains upon which acid groups are statistically implanted. Nafion® forms a sulfonate membrane, as it appears for example from patent application U.S. Pat. No. 3,692,569.

In principle, a proton exchange electrolytic membrane comprises a hydrophobic matrix and hydrophilic zones discretely distributed on said matrix. Insofar as this matrix forms a sort of framework for the membrane, it is sometimes called a skeleton.

This matrix or skeleton comprises amorphous regions and crystalline regions having a hydrophobic character. The hydrophobicity of this matrix is conferred by the fluorocarbon skeleton forming the framework of the membrane. The hydrophilic zones have an acidic character, that is, they comprise one or more acidic functions. In general, as shown in FIG. 2A, the acidic functions are of the SO₃H type.

During the operation of the cell, due to the hydrophobicity of the matrix, the water molecules contacted with the electrolytic membrane are concentrated in the hydrophilic zones close to the acidic groups of this electrolyte. Thus, the water molecules can dissociate these acidic groups, that is, detach the protons therefrom, which can then flow freely in the membrane electrolyte. Nafion® thereby constitutes an electrolyte having good proton conductivity, that is, a conductivity higher than 10 mS/cm.

However, Nafion® is deposited by the liquid method, so that it spreads entirely on the substrate and covers every relief or roughness thereof. This produces a deposit called “nonconforming” because the electrolyte does not reproduce the reliefs of the underlying substrate, thereby limiting the active exchange area, and therefore, the electric power of the fuel cell.

Furthermore, the current method for depositing the Nafion® electrolyte requires the deposition of a minimum thickness of Nafion® of a few tens of microns. In consequence, such a minimal thickness is incompatible with the preparation of a membrane having a large surface area, that is, having many reliefs.

Moreover, Nafion® is relatively sensitive to water and to the solvents used during the fabrication of the fuel cell. This weak chemical resistance entails special precautions to prevent the acidic groups of this material from being prematurely dissolved during the fabrication of the cell, hence before its use.

Other materials have been used to prepare an electrolyte for a fuel cell suitable for conducting protons. Thus the article entitled “New Ultra-Thin Fluorinated Cation Exchange Film Prepared by Plasma Polymerization” by Z. Ogumi, Y. Uchimoto, Z. Takehara and taken from the Journal de la Société d'Eléctrochimie No. 137 (1990), pp. 3319-3320, describes an electrolytic material for preparing a relatively fine membrane about 1 μm thick p. 3320). However, this electrolytic material proved to be a poor proton conductor, having a conductivity of 0.01 mS/cm.

The present invention therefore relates to an electrolytic material which is a good proton conductor, and which is not too sensitive to the method for fabricating the cell. The invention further relates to a method for fabricating such a material, whereof the deposition rate is not too limited.

### SUMMARY OF THE INVENTION

The present invention therefore relates to an electrolytic material having a high proton conductivity and typically higher than 10 mS/cm, having a high deposition rate, that is higher than 2 μm/h, and which resists the water and solvents used during the fabrication of the cell. Moreover, the electrolytic material of the present invention serves to prepare very fine deposits matching the underlying relief.

The material of the invention is suitable for forming an electrolyte of a fuel cell. This material has a hydrophobic matrix comprising carbon, fluorine, oxygen and hydrogen. According to the invention, this matrix further comprises silicon.

According to the rules of the art, the incorporation of silicon is strongly discouraged. Thus, the incorporation of silicon appears, on the one hand, to reduce the hydrophobicity of the matrix, and on the other, increases its crosslinking rate, thereby limiting the capacity of such an electrolyte to absorb water. Thus one would rather expect a decrease in the proton conductivity and a degradation of its chemical and, above all, mechanical resistance.

However, surprisingly, such an electrolytic material incorporating silicon serves to obtain fuel cell membranes having higher chemical and mechanical resistance, high proton conductivity, an aptitude for a fine, matching and rapid deposit, that is, at a relatively high production rate.

In practice, the silicon atoms can form bridges in the matrix, these bridges belonging to the group comprising silicon-silicon (—Si—Si—), silicon-oxygen-silicon (—Si—O—Si—), silicon-oxygen-carbon (—Si—O—C—), and silicon-carbon (—Si—C—) groups.

In other words, the silicon atoms form bonds in the matrix, separately or in combination with oxygen and/or carbon atoms.

According to an embodiment of the invention, this electrolyte may have a ratio of the atomic percentage of silicon to the sum of the atomic percentages of carbon and fluorine of between 10⁻³ and 10⁻¹, preferably between 5×10⁻³ and 5×10⁻².

Such a proportion of silicon in the matrix serves to constitute a material forming an efficient electrolyte in terms of proton conductivity, fineness of deposition, conformity to the reliefs, mechanical and chemical resistance, and production rate.

Advantageously, the matrix may be functionalized by acidic groups.

Such a material is therefore capable, when placed in the presence of water during the operation of the fuel cell, of liberating and conducting the protons (H⁺) issuing from these acidic groups.

Practically speaking, these acidic groups may be selected from sulfonic (—SO₂OH), carboxylic (—COOH) and phosphonic (—PO(OH)₂) groups.

Such acidic groups can be implanted on the matrix of the material using proven methods. Moreover, such acidic groups are capable of liberating their protons when placed in the presence of water at ambient temperature.

In practice, the material of the invention may have a structure selected from the group comprising organic glasses, crystals, polymers, glasses and ceramics.

In other words, the present invention serves to prepare electrolytic materials having various molecular structures. The molecular structure can accordingly be selected according to the desired application.

Furthermore, the present invention relates to a method for fabricating a material for constituting an electrolyte for fuel cell, the material having a matrix comprising carbon, fluorine, oxygen, and hydrogen. According to the invention, this method comprises the steps of:
introducing a gaseous precursor compound of silicon into a plasma chemical vapor deposition chamber;
introducing a fluorocarbon precursor, such as for example octafluorobutene (C₄F₈) or C₂F₄ in the chamber;
introducing a carrier gas into the chamber and for example helium (He);
introducing water vapor (H₂O) into the chamber;
generating a plasma in the chamber.

In practice, the gaseous precursor used is selected from the group comprising the organosilicate compounds hemamethyldisiloxane (HMDSO), tetraethyl-orthosilicate (TEOS), octamethylcyclotetrasiloxane (OMCTSO), tetramethylsilane (TMS), and the inorganic compound silicon tetrahydride (SiH₄). A silicified precursor serves to add silicon atoms to the matrix of the material of the invention.

According to one embodiment of the method of the invention:
the flow rate of gaseous precursor may be between 1 cm³/s and 1000 cm³/s;
the flow rate of the fluorocarbon precursor may be between 1 and 1000 cm³/s;
the carrier gas flow rate may be between 1 cm³/s and 500 cm³/s;
the water vapor flow rate may be between 1 cm³/s and 1000 cm³/s;
the chamber is placed under a pressure of between 0.1 mbar and 5 mbar;
the plasma is excited by capacitive discharges, whereof the power may be between 5 W and 500 W.

Such quantities of reagents and such plasma parameters serve to deposit a material according to the present invention and, in particular, comprising a proportion of silicon characteristic of the invention.

Furthermore, the invention relates to a fuel cell comprising a stack comprising a ceramic substrate porous to hydrogen, a film forming an anode collector, totally or partially covered with an electrolytic membrane made from a material as previously described, and a film forming a cathode collector. Such a fuel cell therefore has improved electrical performance for similar sizes.

In practice, the electrolytic membrane of this cell may have a thickness of between 1 nm and 10 μm.

According to an advantageous embodiment of the invention, the substrate may have many roughnesses and the electrolytic membrane matches these roughnesses.

In the context of the present invention, matching means a deposit whereof the shape faithfully reproduces the relief of the underlying substrate. In other words, it is a deposit having a substantially constant thickness. Thus, the material of the present invention serves to prepare fuel cells whereof the electrolytic membranes are fine and match the relief of the substrate. Such fuel cells therefore have a maximized active surface area.

In practice, the ratio of the real area of the electrolytic membrane to the projected area of the membrane on a plane is higher than 2, and preferably higher than 5.

Such a fuel cell therefore has a high active area suitable for promoting exchanges between anode and cathode. This fuel cell therefore has a high compactness.

Advantageously, the proton conductivity of this electrolyte is between 10 mS/cm and 500 mS/cm.

A fuel cell having such a proton conductivity therefore has improved electric power.

### BRIEF DESCRIPTION OF THE FIGURES

The manner in which the invention can be implemented and the advantages thereof will also appear from the following exemplary embodiments, provided for information and nonlimiting, in conjunction with the figures appended hereto in which:

FIG. 1 is a schematic representation of a cross section of a fuel cell of the prior art. This figure has already been described in relation to the prior art.

FIG. 2A is a schematic representation of an electrolytic material of the prior art. This figure has already been described in relation to the prior art.

FIG. 2B is a schematic representation of an electrolytic material according to the present invention.

FIG. 3 is a schematic representation of a cross section of a fuel cell according to the present invention.

FIG. 4 is a diagram obtained by infrared spectroscopy and illustrating certain structural features of the material of the invention.

FIG. 5 is a diagram obtained by impedance spectroscopy illustrating the proton conductivities of three materials according to the present invention.

### EMBODIMENTS OF THE INVENTION

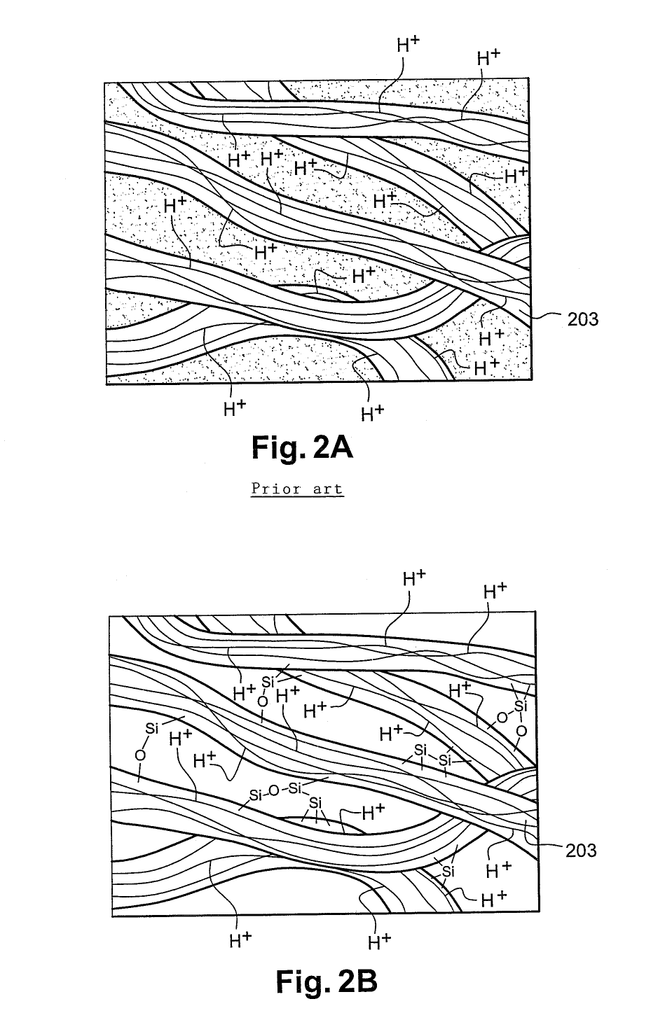

FIG. 2B illustrates, at the scale of 3 μm, the structure of the material of the present invention. According to the invention, this material has a matrix 203 comprising carbon (C), fluorine (F), oxygen (O) and hydrogen (H). As stated previously, this matrix forms the framework of an electrolytic membrane and it is therefore also called a skeleton.

As shown in FIG. 2B, this matrix further comprises silicon (Si), present in the form of bridges formed by silicon-silicon (—Si—Si—), silicon-oxygen-silicon (—Si—O—Si—) and/or silicon-oxygen-carbon (—Si—O—C—), and/or silicon-carbon (—Si—C—) groups. These bridges, by definition, form bonds in the matrix and particularly between the various fibers, shown in FIG. 2B, constituting this matrix.

In the example in FIG. 2B, the silicon atoms account for 1% of the sum of the number of carbon and fluorine atoms present in the matrix 203. Thus, the ratio of the atomic percentage of silicon present in the matrix 203 to the sum of the atomic percentage of carbon and fluorine is 0.01, or 1×10⁻².

Furthermore, as further shown in FIG. 2B, the matrix 203 has acidic groups symbolized by the protons H⁺ bonded to the matrix 203. According to the invention, these acidic groups capable of liberating these protons are selected from the sulfonic (—SO₂OH), carboxylic (—COOH) and phosphonic (—PO(OH)₂) groups.

Thus, when the electrolytic membrane comprising a material according to the invention is contacted with water, its acidic groups are capable of liberating protons, thereby determining the proton conductivity of the membrane, and hence the electrical performance of the fuel cell.

FIG. 3 shows a fuel cell according to the invention, whereof the electrolyte consists of the material of the invention.

Like the fuel cells of the prior art, this fuel cell comprises a stack placed on a ceramic substrate 301 having a thickness of several hundred microns, in this case 600 μm. This stack comprises a ceramic substrate porous to hydrogen 302 covered by a film 303 forming the anode collector, whereof the pole is denoted “+”. The hydrogen is conveyed via channels 305 arranged in the ceramic substrate 301.

In general, the substrate may be a rigid substrate (for example, a silicon substrate) or not (for example, a PET film: polyethyleneterephthalate).

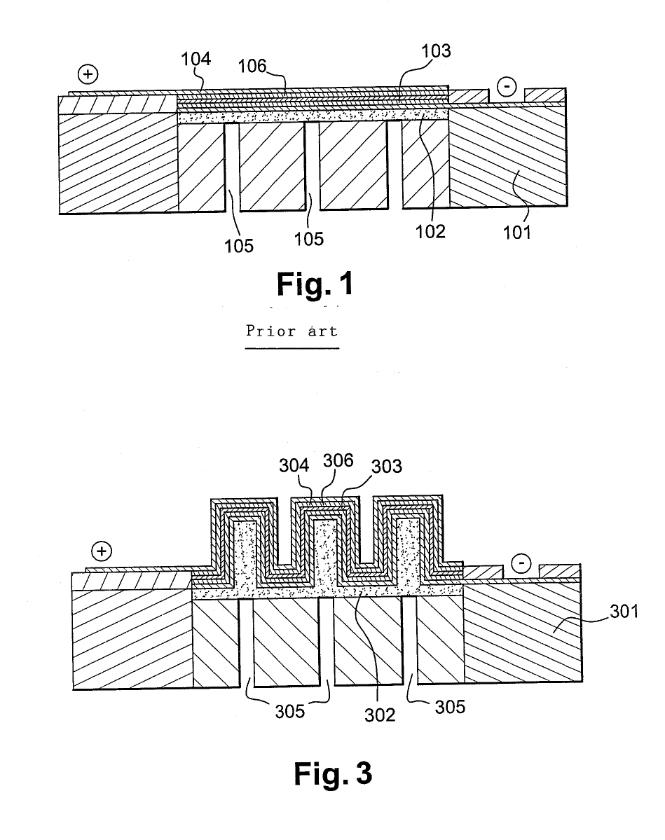

This anode collector is connected to the “+” pole of the fuel cell and is totally covered by an electrolytic membrane 306 made from a material according to the invention. Moreover, like the cell of the prior art shown in FIG. 1, the electrolytic membrane 306 is covered by a film forming the cathode collector, whereof the pole is denoted “−”.

As shown by the comparison of FIGS. 1 and 3, unlike the fuel cell in the prior art shown in FIG. 1, the fuel cell of the invention has a number of roughnesses, in this case three studs located in the cross-sectional plane. These roughnesses form as many reliefs designed to increase the active real area of the electrolytic membrane and therefore to improve the electrical performance of the fuel cell without increasing its overall dimensions.

In actual fact, the ratio of the real area of this membrane to the apparent area thereof, that is, the projected area on a horizontal plane, is much higher than in the case in FIG. 1, where the electrolytic membrane 106 is purely plane. In fact, in a projection on a horizontal plane, the electrolytic membranes 106 and 306 have the same apparent area in the case in which the two cells have similar dimensions. However, provided with its reliefs, electrolytic membrane 306 has a much higher real area than the area of the plane membrane 106. The ratio between the real area and the apparent area is close to 2 here.

Such a “rough” structure is made possible, thanks to the ability of the material of the present invention to form a matching deposit, that is a thin deposit reproducing the underlying relief upon which it is deposited. In the present case, the membrane 306 has a thickness of 1 μm, which is much lower than the thicknesses of the membranes of the prior art for a similar proton conductivity.

In fact, the electrolyte 306 of the fuel cell shown in FIG. 3 has a conductivity of several tens of mS/cm.

Thus, the electrical performance of the fuel cell shown in FIG. 3, comprising a matching proton conducting organic glass, is very substantially increased. This electrical performance is evaluated as the power delivered related to the apparent area of the membrane.

Furthermore, the material of the invention also serves to increase the electrical performance of a fuel cell, insofar as it may be deposited in a reduced thickness. In fact, such a thickness reduction, for the same resistivity, serves to reduce the internal resistance of the proton conducting electrolyte. In fact, the thickness of the electrolytic membrane comprising a material according to the invention can be controlled to the nearest micron, thereby giving rise to membrane thicknesses one hundred times lower than the membrane thicknesses of the prior art. In consequence, the electrolytic membrane 306 has a much lower internal resistance, hence a higher conductivity than that of the electrolytic membrane 106.

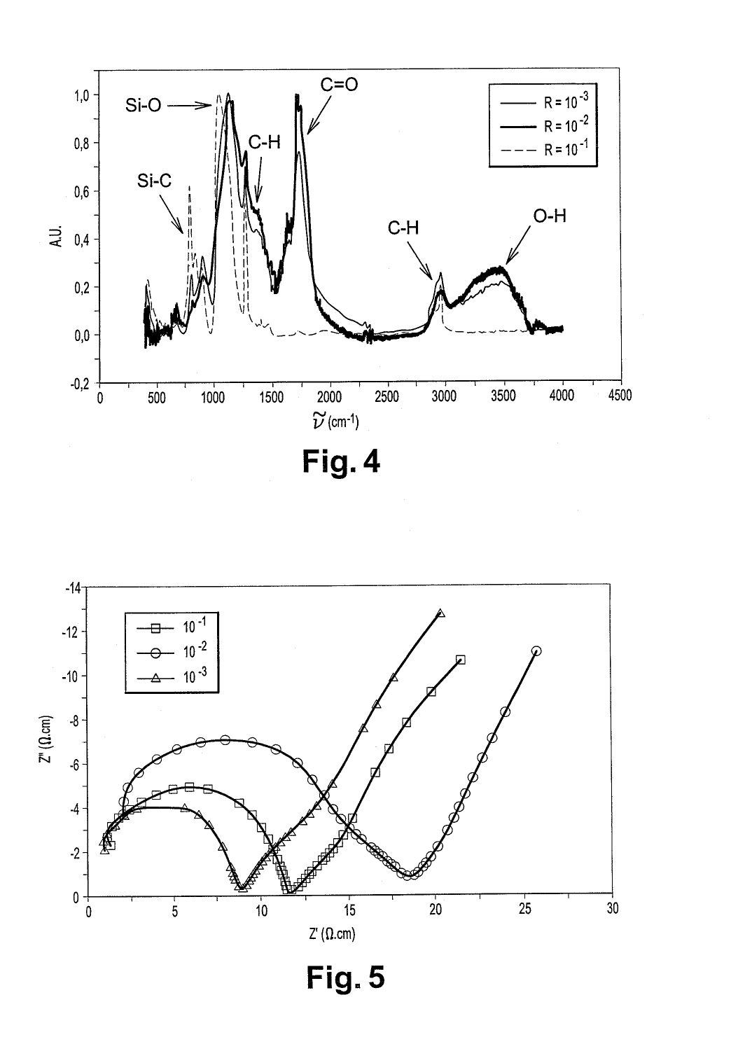

FIG. 4 is a diagram obtained by infrared spectroscopy showing the characteristic groups of the matrix of the material of the invention. The curves in FIG. 4 respectively show the ratios R=10⁻¹, 10⁻² and 10⁻³ between the silicon atoms on the one hand, and the carbon and fluorine atoms on the other. The ratio R is therefore N_{Si}/(N_{C}+N_{F}), where N is the number of atoms.

It can thus be observed that the first two peaks for the wave numbers located respectively around 750 cm⁻¹ and 1100 cm⁻¹ correspond to the bridges composed of silicon, that is respectively —Si—C— and —Si—O—. The y-axis is graduated in arbitrary units.

The infrared spectra also reveal a peak corresponding to the wave number 1750 cm⁻¹ indicating the presence of carboxylic (COOH) groups implanted to functionalize the matrix of the material of the present invention.

FIG. 5 shows a diagram in which are plotted the measurement of the conductivity obtained by impedance spectroscopy carried out on electrolytic membranes comprising materials respectively having the atomic ratios R=10⁻¹, 10⁻² and 10⁻³. The conductivities are respectively 5 mS/cm, 25 mS/cm and 120 mS/cm.

Furthermore, experiments have served to establish the chemical resistance of electrolytic membranes comprising a material according to the invention. Thus, two membranes, one without silicon (R=0) and the other silicified (R=1) were introduced into a deionized water bath for 30 min. After this immersion, it was found that the silicon-free membranes were 90% destroyed, whereas the silicified membranes had an unchanged structure.

A crosscheck of the conductivity and water resistance measurements reveals an optimum ratio R estimated between 5×10⁻³ and 5×10⁻², serving to obtain good chemical resistance while preserving satisfactory conductivity (>25 mS/cm).

This property thereby constitutes an important advantage, because such silicified membranes are capable of chemically and/or mechanically resisting the water employed in the fabrication method of a fuel cell. Furthermore, the silicified membranes are also capable of resisting other solvents harmful to silicon-free membranes.

To fabricate such a material, the method consists in introducing a gaseous precursor compound of silicon (Si) into a plasma induced chemical vapor deposition chamber. At the same time, octafluorobutene (C₄F₈), helium (He) and water vapor (H₂O) are introduced into said chamber. However, another fluorocarbon compound could be used, such as C₂F₄, and also another carrier gas, such as argon or hydrogen. The flow rates of these gases are about a few hundreds of cm³/s. With these gases, a low pressure plasma is generated, excited by capacitive discharges whereof the radio-frequency is 13.56 MHz (this value is imposed by the electromagnetic compatibility standards). Other types of plasma excitation can be used, however, such as the low frequencies described (10 kHz to 400 kHz), or microwaves (2.45 GHz).

An electrolyte is thereby deposited in membrane form matching the relief of the underlying ceramic substrate with an industrial deposition rate of about 2 μm/h. Knowing the deposition rate of the electrolyte, the total thickness of the matching membrane can be controlled accurately by adjusting the plasma deposition time. This rate can be raised to 5 μm/h by increasing the power density of the plasma.

Such a production rate serves to produce the material of the present invention at an industrial rate, hence compatible with the applications envisioned for nomad fuel cells.

Furthermore, as previously stated, the texturing of the surface of the porous ceramic substrate may be uniform or nonuniform, or even completely random. Regardless of the relief selected, the method previously described serves to prepare a matching deposit of a material forming a proton conducting electrolyte.

Other embodiments of the invention are feasible without necessarily going beyond the scope of said invention.

1. A method for preparing a material for constituting an electrolyte (306) for fuel cell, said material having a matrix comprising carbon, fluorine, oxygen, hydrogen and silicon, wherein it comprises the steps of:
introducing a gaseous precursor compound of silicon into a plasma chemical vapor deposition chamber;
introducing a fluorocarbon precursor into the chamber;
introducing a carrier gas into the chamber;
introducing water vapor into the chamber;
generating a plasma in the chamber after the introduction of these various compounds.

2. The method as claimed in claim 1, wherein the fluorocarbon precursor is selected from the group comprising C₄F₈ and C₂F₄.

3. The method as claimed in claim 1, wherein the silicon compound precursor is selected from the group comprising the organosilicate compounds hemamethyldisiloxane (HMDSO), tetraethyl-orthosilicate (TEOS), octamethylcyclotetrasiloxane (OMCTSO), tetramethylsilane (TMS), and the inorganic compound silicon tetrahydride (SiH₄).

4. The method as claimed in claim 1, wherein:
the flow rate of said gaseous precursor is between 1 cm³/s and 1000 cm³/s;
the flow rate of fluorocarbon precursor is between 1 cm³/s and 1000 cm³/s;
the carrier gas flow rate is between 1 cm³/s and 500 cm³/s;
the water vapor flow rate is between 1 cm³/s and 1000 cm³/s;
a the chamber is placed under a pressure of between 0.1 mbar and 5 mbar;
the plasma is excited by capacitive discharges, whereof the power is between 5 W and 500 W.

5. A material for constituting an electrolyte for fuel cell obtained using the method as claimed in claim 1, wherein the electrolyte has a ratio of the atomic percentage of silicon to the sum of the atomic percentages of carbon and fluorine of between 10⁻³ and 10⁻¹, preferably between 5×10⁻³ and 5×10⁻².

6. The material suitable for constituting an electrolyte for fuel cell as claimed in claim 5, wherein it has a thickness of between 1 nm and 10 μm.

7. A fuel cell wherein it comprises a stack comprising a substrate porous to hydrogen, a film forming an anode collector, totally or partially covered with an electrolytic membrane made from a material as claimed in claim 5, and a film forming a cathode collector.

8. The fuel cell as claimed in claim 7, wherein the substrate has many roughnesses and wherein the electrolytic membrane matches said roughnesses.

9. The fuel cell as claimed in claim 8, wherein the ratio of the real area of the electrolytic membrane to the projected area of the electrolytic membrane on a plane is higher than 2, and preferably higher than 5.
